(19) United States
(12) Patent Application Publication
(10) Pub. No.: US 2005/0045993 A1
(43) Pub. Date: Mar. 3, 2005

(54) Semiconductor device with concave patterns in dielectric film and manufacturing method thereof

(75) Inventors: Michinori Okuda, Anpachi-Gun (JP); Yoshinari Ichihashi, Hashima-shi (JP); Yoshikazu Yamaoka, Ogaki-shi (JP); Yasunori Inoue, Ogaki-shi (JP); Yuko Tanaka, Anjo-Si (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 10/915,460

(22) Filed: Aug. 11, 2004

(30) Foreign Application Priority Data
Aug. 28, 2003 (JP) 2003-305390
Aug. 28, 2003 (JP) 2003-305393
May 19, 2004 (JP) 2004-148604

(51) Int. Cl. H01L 21/336

(52) U.S. Cl. 257/618

(57) ABSTRACT

When a plurality of through holes is formed in a interlayer dielectric film including Si, O, and C at least, a plurality of dummy through holes is formed in the circumference of a cluster of through holes and an isolated through hole. And/or the etching-gas with a higher content of a nitrogenous gas is used, and the etching is performed step by step using the etching gases containing C₄F₆ and not containing C₄F₆. And/or the carbon content ratio in the etching gas defined by
p=X×(Qc/Q)×100
where X is a carbon component ratio X in a fluorocarbon gas represented by C_{X}F_{Y}, Q is a total flow rate of the etching gas, and Qc is a gas flow rate of fluorocarbon C_{X}F_{Y}, is set to 5% or less.

### BACKGROUND OF THE INVENTION

1. Field of the Invention

The present invention relates to a semiconductor device and manufacturing method thereof, in particular to the semiconductor device with a plurality of concave patterns formed in a dielectric film, and the manufacturing method thereof.

2. Description of the Related Art

Recently, a multilayer interconnect line is becoming scaled down as one of the solutions to problems such as high-speed operation of a semiconductor device and reduction of the manufacturing cost. On the other hand, the problem of interconnect delay (RC delay) caused by the increase in interconnect resistance and capacitance between interconnect lines was brought to light, and it came to a major limiting factor in the operating speed of the semiconductor device. Consequently, some measures became widely known, for example, to use copper (Cu) as a material for an interconnect line to reduce the interconnect resistance, or to use a low dielectric constant material with a dielectric constant lower than that of a conventional material, SiO₂, for a dielectric film to reduce the capacitance between interconnect lines.

The materials such as SIOC and MSQ (Methyl Silsesquioxane) are examined as such a low dielectric constant material. It is expected that the technology for usual SiO₂ film can be transferred to these materials, and the development of these materials is advanced also because of the easy treatment.

However, some problems, which do not occur in case of SiO₂ film, sometimes occur when through holes are formed in SiOC film by using a gas of fluorocarbon that is conventionally used as an etching-gas to form though holes in SiO₂ film, because of the characteristic difference of these films.

For example, Japanese Patent Laid Open Publication 2002-83798 discloses the phenomenon wherein the etching process stops on the way when SiOC film is etched by using a gas of fluorocarbon. Furthermore, there is the problem of decreasing in the ratio of etching speed of a resist film to SiOC film when the oxygen content is increased to prevent such a phenomenon. The related art also discloses the technology to add CO to the etching gas as a solution of these problems.

Related Art List

JPA laid open 2002-83798

### SUMMARY OF THE INVENTION

However, in prior art, it is not fully grasped about the characteristic phenomenon which occurred in dry etching of the film such as SiOC film, and there is room for a process improvement.

The inventors of the present invention found new phenomena shown in the following as a result of the earnest study about the dry etching process of such films as SiOC. That is, when a pattern including of a plurality of through holes was formed by dry etching of SiOC film, it was found that:
(i) the difference in etching rates arose between at the center part of the cluster of through hole patterns and at the edge part thereof, and
(ii) this difference in etching rates changed by the component ratio of the etching gas.

Such the ununiformity in etching rates induces the problems such as an etching residue in through holes in the region with a low etching rate, and an under layer film, such as a diffusion barrier film, thinned by excessive etching in the region with a high etching rate. As a result, the etching induces a difference in dimension conversion in the depth direction, and a yield rate declines.

The present invention is achieved in view of the aforementioned circumstances and an object thereof is to provide a technique capable of reducing the unniformity in etching rates of a plurality of concave patterns and reducing the differences in dimension conversion in the depth direction induced by etching in semiconductor device manufacturing.

As mentioned above, the inventors of the present invention found that the problem of the difference in etching rates of through holes, which does not occur in SiO₂ usually used, occurred when SIOC was used for a dielectric film. Thus the inventors of the present invention gave thought to an idea of the first through the third group of inventions as will be described in detail below, as a result of doing an examination about the arrangement of through holes, and the kind and the composition of the etching gas.

First, the invention that belongs to the first group is described.

The semiconductor device according to one aspect of the first group of the present invention includes: a dielectric film; a plurality of concave patterns formed in the dielectric film; and a plurality of dummy concave patterns formed in the dielectric film and arranged in the surroundings of the plurality of concave patterns.

The concave pattern can be a through hole or a trench for interconnection. The surroundings can be circumference of a cluster of concave patterns when a plurality of concave patterns is arranged adjacently each other constituting a cluster. When a plurality of concave patterns includes an isolated concave pattern surrounded by no other concave pattern, the surroundings can be circumference of the isolated concave pattern. On the other hand, the dummy concave pattern can be arranged surrounding all concave patterns. Here, the surroundings can be on all four sides of the concave patterns. When the plane divided into approximately quarters with setting each concave pattern into the central point of dividing, the dummy concave patterns can be formed so that the concave patterns exist within the prescribed distance from the other concave pattern on all parts of the divided plane.

The dielectric film can have a composition which includes Si, O and C at least. The dielectric film can include H. SiOC, SiOCN or MSQ can be used for the dielectric film for example. SiOC or SiOCN can be formed by a CVD method or a spin coat method. MSQ can be formed by a spin coat method. The gas of fluorocarbon can be used as the etching gas to form these concave patterns.

In the semiconductor device according to the first group of the present invention, the plurality of concave patterns can be arranged in a block, and the plurality of dummy concave patterns can be arranged along the outermost regions of the plurality of concave patterns. The block includes a matrix i.e., a rectangular arrangement consisting of rows and columns, a row arranged in a longitudinal or transverse directions, a plurality of concave patterns arranged at random, a plurality of concave patterns of which density varies, a plurality of concave patterns arranged in a comb row, and so on.

The area including a plurality of through holes that contributes electric movement of a semiconductor device can be considered as a block, and the dummy concave patterns can be arranged in the circumference of the block. Furthermore, when a short-circuited area to connect the interconnect lines in the upper and the lower layers electrically exists near the plurality of concave patterns, the dummy concave patterns can be arranged in the circumference of the region including the plurality of concave patterns and the short-circuited area.

The semiconductor device according to another aspect of the first group of the present invention includes: a dielectric film; and a plurality of concave patterns formed in the dielectric film, wherein the plurality of concave patterns is formed so that the opening width of the concave pattern surrounded by no other concave pattern is different from that of the concave pattern surrounded by other concave patterns.

The dielectric film may have a composition which includes Si, O and C at least. The dielectric film can include H. SiOC, SiOCN or MSQ can be used for the dielectric film, for example. SiOC or SiOCN can be formed by a CVD method or a spin coat method. MSQ can be formed by a spin coat method. The gas of fluorocarbon can be used as the etching gas to form these concave patterns.

The magnitude relation of the opening widths of the concave patterns surrounded by no other concave pattern and that surrounded by other concave patterns are properly determined corresponding to the kind of etching gas. When the etching rate of the concave pattern surrounded by no other concave pattern is lower than that of the concave pattern surrounded by other concave patterns, the opening width of the concave pattern surrounded by no other concave pattern can be larger than that of the concave pattern surrounded by other concave patterns. With this construction, the etching rate of the concave pattern surrounded by no other concave pattern can be increased by a micro-loading effect.

On the other hand, when the etching rate of the concave pattern surrounded by no other concave pattern is higher than that of the concave pattern surrounded by other concave patterns, the opening width of the concave pattern surrounded by no other concave pattern can be smaller than that of the concave pattern surrounded by other concave patterns. With this construction, the etching rate of the concave pattern surrounded by no other concave pattern can be decreased.

The manufacturing method of a semiconductor device according to one aspect of the first group of the present invention includes the steps of: forming a dielectric film; and forming a plurality of concave patterns and a plurality of dummy concave patterns in the dielectric film, wherein the plurality of dummy concave patterns is formed in the surroundings of the plurality of concave patterns at the step of forming the plurality of concave patterns.

The manufacturing method of a semiconductor device according to another aspect of the first group of the present invention includes the steps of: forming a dielectric film; and forming a plurality of concave patterns in the dielectric film, wherein the plurality of concave patterns is formed so that the opening width of the concave pattern surrounded by no other concave pattern is different from that of the concave pattern surrounded by other concave patterns at the step of forming the plurality of concave patterns.

Secondly, the invention that belongs to the second group is described

As a result of the earnest studies about the gas composition, the inventors of the present invention found that the unniformity in etching rates could be reduced by an etching gas with a larger content of nitrogenous gas than a certain amount. It can be achieved regardless of the arrangement of concave-patterns. It follows that the shape in the depth direction of a plurality of concave patterns can be stably formed.

Moreover, it found that the etching rate at the edge part of a block including concave patterns and at an isolated concave pattern could be increased by using C₄F₆ as a gas of fluorocarbon. Here, the meaning of a block includes a plurality of concave patterns arranged in a cluster, wherein the concave patterns can be properly arranged in a matrix, in a vertical row, or a horizontal row, for example. A plurality of concave patterns can be also arranged at random.

The manufacturing method of the semiconductor device according to one aspect of the second group of the present invention includes the steps of: forming a dielectric film containing Si, O and C at least; and forming a plurality of concave patterns in the dielectric film by dry etching using a etching gas containing a nitrogenous gas, wherein a content of the nitrogenous gas in the etching gas is 23% or more by gas flow ratio.

The gas such as N₂ and ammonia can be used as the nitrogenous gas. The etching gas can contain the gas of fluorocarbon. SiOC, SiOCN or MSQ can be used for the dielectric film, for example. SiOC or SiOCN can be formed by a CVD method or a spin coat method. MSQ can be formed by a spin coat method.

The manufacturing method of a semiconductor device according to another aspect of the second group of the present invention includes the steps of: forming a dielectric film containing Si, O and C at least; and forming a plurality of concave patterns in the dielectric film by dry etching using the first etching gas containing C₄F₆.

The etching gas can contain no oxygen substantially. This means that the oxygen content has a gas flow ratio of 2% to 3% or less, for example.

The step of forming the plurality of concave patterns can include the step of dry etching using the second etching gas containing one or more gases of fluorocarbon selected from CH₂F₂, CF₄ and C₄F₈, and the dry etching using the first etching gas can be performed before or after the step of dry etching using the second etching gas.

Thus, even if a difference in etching rates arises depending on the arrangement of concave patterns after the first dry etching, such a difference can be canceled by the next dry etching, by performing the step-by-step dry etching with different kinds of fluorocarbon gas.

The processing time of each dry etching step using respective gases can be properly fixed according to the kind of contained gas or the kind of the nitrogenous gas in the etching gas.

The first etching gas can contain CF₄ additionally, and the gas flow ratio of C₄F₆ to CF₄ can be smaller than 1. With this, the concentration of C₄F₆ in the etching gas can be reduced, and the easier control can be achieved as a result. The content of C₄F₆ in the first etching gas preferably ranges from 1% to 3% by gas flow ratio, for example.

Next, the invention that belongs to the third group is described.

After the further investigation about the gas composition, the inventors of the present invention found that the relation between the composition ratio of the etching gas and the etching rate could be arranged clearly by introducing a new index defined as follows:
Carbon content ratio in etching gas p=X×(Qc/Q)×100 (1)
where X is a carbon component ratio in a fluorocarbon gas, Q is a total flow rate of the etching gas, and Qc is a flow rate of fluorocarbon gas. The carbon component ratio X means the component ratio contained in fluorocarbon molecule, and for example, it corresponds to X when the fluorocarbon is expressed in the molecular formula of C_{X}F_{Y}.

The inventors of the present invention thought that an index showing the ratio of the number of carbon atoms reaching the etched surface to the number of all particles was important as a factor that controls the relation between the composition ratio of the etching gas and the etching rate. The carbon content ratio p shows the ratio of the number of carbon atoms to the number of all molecules introduced into the apparatus, and has a close relationship to such an index.

As will hereinafter be described, in the range where the carbon content ratio in the etching gas p defined above is relatively low, the etching rates at the center region and the edge of a cluster consisting of a plurality of concave patterns become relatively uniform. Whereas in the range where the carbon content ratio p is relatively high, the etching rate at the edge of patterns becomes larger compared with that at the center region. The invention belonging to the third group was developed on the basis of such novel knowledge.

The manufacturing method of a semiconductor device according to one aspect of the third group of the present invention includes the steps of: forming a dielectric film containing Si, O and C; and forming a plurality of concave patterns in the dielectric film by dry etching using an etching gas containing a fluorocarbon, wherein the carbon content ratio in the etching gas, p(%), defined by
p=X×(Qc/Q)×100
where X is a carbon component ratio in a fluorocarbon, Q is a total flow rate of the etching gas, and Qc is a flow rate of a fluorocarbon gas, is 5% or less.

The manufacturing method of a semiconductor device according to another aspect of the third group of the present invention includes the steps of: forming a dielectric film containing Si, O and C; and forming a plurality of concave patterns in the dielectric film, wherein the step of forming the plurality of concave patterns includes the steps of the first dry etching using the first etching gas containing a fluorocarbon and the second dry etching using the second etching gas containing a fluorocarbon, and the carbon content ratio p(%), defined by
p=X×(Qc/Q)×100
where X is a carbon component ratio in a fluorocarbon, Q is a total flow rate of the etching gas, and Qc is a flow rate of a fluorocarbon gas, in either the first etching gas or the second etching gas is less than that in another.

The first dry etching can be performed either before or after the second dry etching. The ratio of amount of the first and the second dry etchings, i.e., the ratio of processing time of each dry etching step, can be properly fixed according to the carbon content ratio in the etching gas used in each step. The kinds of fluorocarbon gas contained in the etching gases used in the first and the second dry etching steps can be either same or different.

In the manufacturing method mentioned above, the carbon content ratios p in the first and the second etching gases are preferably defined so that the etching rate at the center region of a cluster consisting of a plurality of concave patterns is higher compared with that at the edge during the first dry etching step, and the etching rate at the edge of a cluster consisting of a plurality of concave patterns is higher compared with that at the center region during the second dry etching step. With this, the difference in the etching rates induced by the first dry etching can be reduced by the second dry etching.

Besides fluorocarbon, such inert gas as Ar, or such-gas as N₂ and NH₃ can be used for etching to form a plurality of concave patterns in the present invention belonging to the third group.

Optional combinations of the aforementioned constituting elements, and implementations of the invention in the form of other category may also be practiced as additional modes of the present invention.

### BRIEF DESCRIPTION OF THE DRAWINGS

FIG. 1A shows an arrangement of through holes formed in a reference example.

FIG. 1B is an example of a cross sectional view taken in the line 1B-1B of FIG. 1A.

FIG. 2 shows etching rates when through holes are formed by using fluorocarbon as an etching gas in the reference example for the first group of the present invention.

FIG. 3 shows etching rates with a variation of dielectric film material and etching gas in the reference example for the first group of the present invention.

FIG. 4A shows a construction of a semiconductor device in the first embodiment of the first group of the present invention.

FIG. 4B is an example of a cross sectional view taken in the line 4B-4B of FIG. 4A.

FIG. 5A shows an example of an arrangement of dummy through holes in the first embodiment of the first group of the present invention.

FIG. 5B shows another example of an arrangement of dummy through holes in the first embodiment of the first group of the present invention.

FIG. 5C shows still another example of an arrangement of dummy through holes in the first embodiment of the first group of the present invention.

FIG. 5D shows still another example of an arrangement of dummy through holes in the first embodiment of the first group of the present invention.

FIG. 6A shows still another example of an arrangement of dummy through holes in the first embodiment of the first group of the present invention.

FIG. 6B shows still another example of an arrangement of dummy through holes in the first embodiment of the first group of the present invention.

FIG. 7 shows still another example of an arrangement of dummy through holes in the first embodiment of the first group of the present invention.

FIG. 8A shows a construction of a semiconductor device in the second embodiment of the first group of the present invention.

FIG. 8B is an example of a cross sectional view taken in the line 8B-8B of FIG. 8A.

FIG. 9 shows an arrangement of through holes formed in an example of the first group of the present invention.

FIG. 10 shows etching rates when the through holes shown in FIG. 9 were formed.

FIG. 11 shows another example of an arrangement of dummy through holes in an embodiment of the first group of the present invention.

FIG. 12A shows still another example of an arrangement of dummy through holes in an embodiment of the first group of the present invention.

FIG. 12B shows still another example of an arrangement of dummy through holes in an embodiment of the first group of the present invention.

FIG. 13 shows still another example of an arrangement of dummy through holes in an embodiment of the first group of the present invention.

FIG. 14 shows still another example of an arrangement of dummy through holes in an embodiment of the first group of the present invention.

FIG. 15 schematically shows a part of an overall construction of a circuit wherein a plurality of through holes are formed in an embodiment of the first group of the present invention.

FIG. 16A shows an arrangement of through holes formed in a reference experiment of the second group of the present invention.

FIG. 16B shows an example of a cross sectional view taken in the line 16B-16B of FIG. 16A.

FIG. 17 shows etching rates with a variation of dielectric film material and etching gas in the reference experiment of the second group of the present invention.

FIG. 18 shows a top view of a dielectric film with through holes in the first example of the second group of the present invention.

FIG. 19 is a graph showing etching rates with a variation of content of N₂ in etching gas in the first example of the second group of the present invention.

FIG. 20 shows a graph showing etching rates when the C₄F₆ is contained in etching gas in the third example of the second group of the present invention.

FIG. 21A shows an arrangement of through holes formed in a reference experiment of the third group of the present invention.

FIG. 21B shows an example of a cross sectional view taken in the line 21B/21C-21B/21C of FIG. 21A.

FIG. 21C shows another example of a cross sectional view taken in the line 21B/21C-21B/21C of FIG. 21A.

FIG. 22 shows a top view of a dielectric film with through holes in the first example of the third group of the present invention.

FIG. 23 is a graph showing etching rates with a variation of carbon content ratio in etching gas that contains C₄F₈ in the first example of the third group of the present invention.

FIG. 24 is a graph showing etching rates with a variation of carbon content ratio in etching gas that contains CF₄ and C₄F₆ in the first example of the third group of the present invention.

### DETAILED DESCRIPTION OF THE INVENTION

### REFERENCE EXAMPLE

First, a reference example wherein a plurality of through holes is formed under some etching conditions will be explained to indicate the characteristics of the present invention.

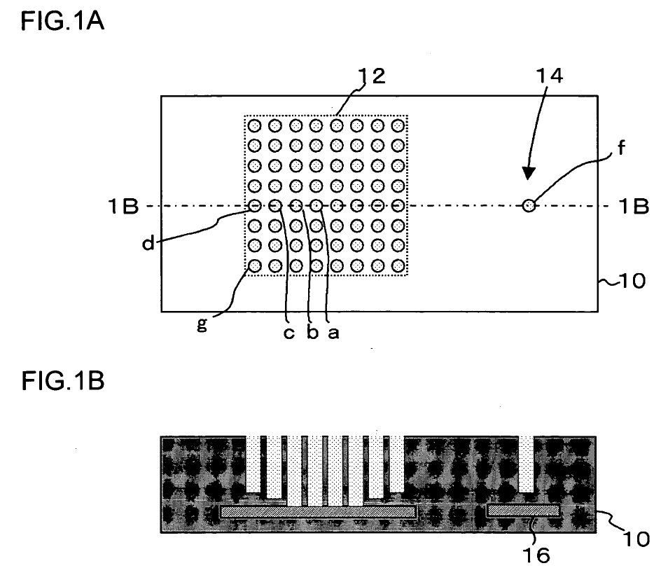

FIGS. 1A and 1B show through hole patterns formed in the present example.

As shown in FIG. 1A, the cluster consisting of a plurality of through holes 12 arranged in a matrix, and the isolated through hole 14 with no other through hole nearby are formed in the interlayer dielectric film 10. After etching of through holes in such a pattern using a gas of fluorocarbon, through holes shown in FIG. 1B are formed. FIG. 1B is an example of a cross sectional view taken in the line 1B-1B of FIG. 1A. The etching rates of the through hole c and d formed at the edge part of the cluster of through holes 12 are lower, compared with that of the through hole a and b formed in the center region as shown in FIG. 1B. The etching rate of the isolated through hole 14 (through hole f) is further low compared with that of the through hole included in the cluster of through holes 12. On the other hand, the phenomenon that the etching rate of a through hole formed in the outermost region of the matrix of plural through holes becomes higher than that of a through hole formed in the center region also occurs depending on the kind of etching gas. Like this, the etching rate in the outermost region of a block including a plurality of through holes varies more widely than the etching rate in the center region when the through holes are formed in SIOC film by etching.

Next, the preferable embodiments belonging to the first through the third groups of the present invention will be explained referring to figures with showing the results of reference experiments about the etching of the through holes shown in FIG. 1A or equivalent.

### THE FIRST GROUP

### REFERENCE EXPERIMENT

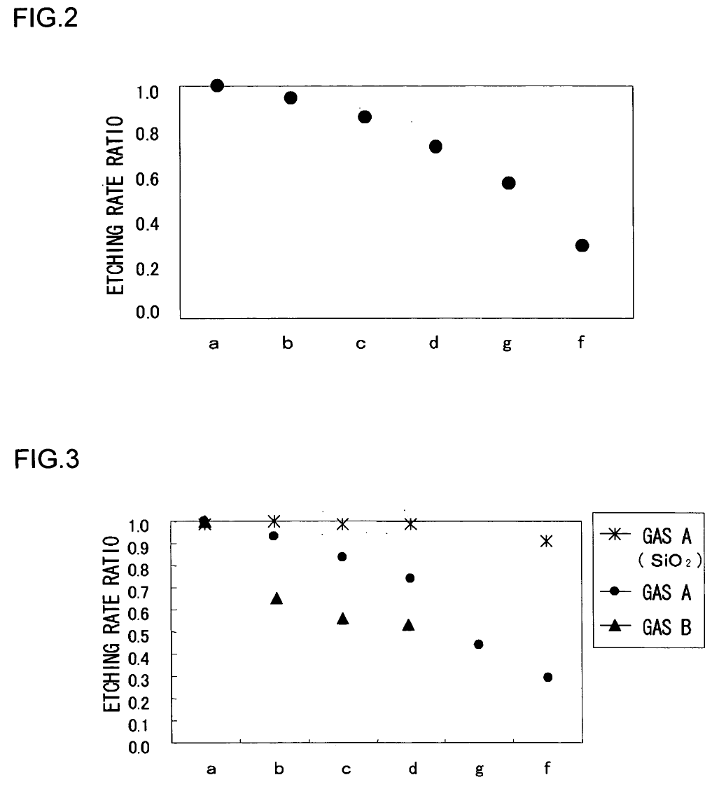

First, the result of the reference experiment is described. FIG. 2 shows etching rate ratios when the through holes in the arrangement shown in FIG. 1 were etched by using a mixed gas of Ar/CF₄/CH₂F₂/N₂ as a fluorocarbon gas. When the etching rate of the through hole a formed in the center of the cluster of through holes 12 was set to 1, the etching rate of the through hole d located in the outermost side of the cluster of through holes 12 was about 0.7, the etching rate of the through hole e located in the outermost corner of the cluster of through holes 12 was about 0.6, and the etching rate of the isolated through hole f is about 0.3. Although the through hole a is shown to be adjacent to the through hole b in FIG. 1A, plural through holes, about ten through holes for example, were formed between the trough hole a and the through hole b practically. Therefore, the etching rate of the through hole a shown in FIG. 2 is the value when the through hole a is surrounded by ten or more through holes in every direction. Same applies to FIG. 3.

FIG. 3 shows etching rates with a variation of the material of the interlayer dielectric film and the etching gas.

The etching rates shown in FIG. 3 are the results:
(1) when SiO₂ was used for the interlayer dielectric film, and the gas A was used as the etching gas;
(2) when SiOC was used for the interlayer dielectric film, and the gas A was used as the etching gas; and
(3) when SiOC was used for the interlayer dielectric film, and the gas B was used as the etching gas.

The conditions of the etching gases A and B were: a gas flow rate of Ar/CF₄/CH₂F₂/N₂=500/30/10/90 sccm, a pressure of 50 mTorr and an RF power of 1300 W; and a gas flow rate of Ar/C₄F₈/N₂=500/8/50 sccm, a pressure of 50 mTorr and an RF power of 1300 W, respectively.

The diameter of the through hole was 0.2 μm. When SiO₂ was used for the interlayer dielectric film, there was little difference in the etching rates depending on the state of arrangement of through holes. On the other hand, when SiOC was used for the interlayer dielectric film, it was found that the difference in the etching rates depending on the location of the through hole in the arrangement arose regardless of the kind of etching gas. This result provides that the difference in the etching rates depending on the state of arrangement of through holes is induced depending on the material of the interlayer dielectric film, not on the material of a resist film used for etching nor the kind of the etching gas.

Next, an embodiment is explained specifically. In the following preferable embodiments, the examples of forming SiOC film or SiOCN film by a CVD method, or forming MSQ film by a spin coat method as a material of interlayer dielectric films are explained. SiOC film is sometimes written with SiOCH film, and it usually contains Si, O, C and H as the composition elements. A stacked structure which contains such films as SiO₂, SiN and SiON in addition to SiOC film or MSQ film can be introduced as the interlayer dielectric film.

### THE FIRST EMBODIMENT IN THE FIRST GROUP

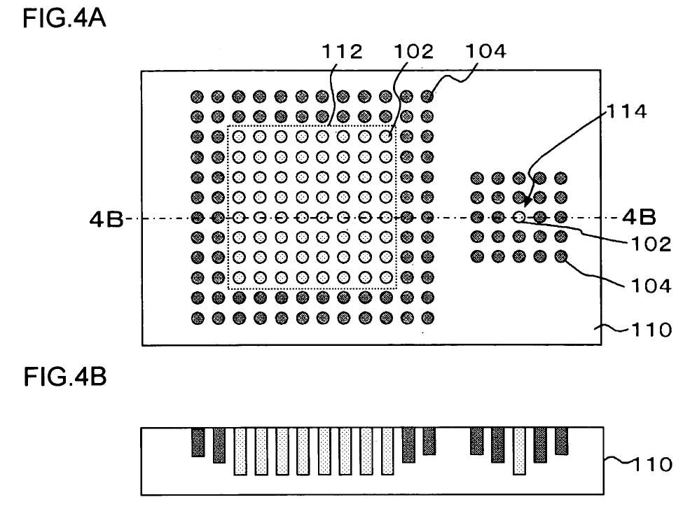

FIGS. 4A and 4B show constructions of a semiconductor device in the first embodiment of the first group of the present invention.

Although only the interlayer dielectric film 110 is illustrated in this figure, a semiconductor device includes a substrate such as silicon, and has a structure wherein such layers as a diffusion barrier film, an etching stopper film, an antireflective film, and the lower interconnect layer are properly formed on the substrate. Furthermore, the upper interconnect layer etc. are formed on the interlayer dielectric film 110.

The cluster of through holes 112 consisting of a plurality of through holes 102 arranged in a matrix and the isolated through hole 114, i.e., the through hole 102 arranged in isolation, are formed in the interlayer dielectric film 110. The plurality of dummy through holes 104 are formed in the circumference of the cluster of through holes 112. The plurality of dummy through holes 104 are also formed in the circumference of the isolated through hole 114. The through holes 102 are electrically connected with the upper and the lower interconnects, and the through holes 102 contribute to electric movement of the semiconductor device. On the other hand, the dummy through holes 104 do not contribute to the electric movement of the semiconductor device. The dummy through holes 104 are constructed not to connect the upper and the lower interconnects electrically, though the dummy through holes 104 may be connected with either the upper or the lower interconnect.

The dummy through holes 104 are arranged so that all of the through holes 102 is surrounded by at least 2 through holes, i.e., the through holes 102 and/or the dummy through holes 104, in a vertical, a horizontal, and a oblique direction respectively. The arrangement pattern of the dummy through holes 104 can be properly determined depending on the material of the interlayer dielectric film 110, the kind of the etching gas used to form the through holes 102 in the interlayer dielectric film 110, the opening width of the through holes 102, the interval of the through holes 102, and so on.

FIG. 4B is a cross sectional view taken in the line 4B-4B of FIG. 4A. As shown in FIG. 4B, the phenomenon of decrease or increase in the etching rate, which originally occurs in the through holes 102 located in the outermost region of the cluster of through holes 112, shifts to the dummy through holes 104. With this, the difference in the depths of the through holes 102 caused by the difference in the etching rates is reduced. As a result, the shape of the through holes 102, which is electrically connected with the lower and the upper interconnects, can be formed steadily and equally.

When the etching gas by which the through holes formed in the outermost region are etched with a lower etching rate is used, the dummy through holes do not reach the lower interconnect layer when the through holes 102 reaches the lower interconnect layer, since the etching rates of the dummy through holes 104 are lower than those of the through holes 102. Therefore, the construction wherein the dummy through holes 104 are not opened to the lower interconnect layer can be achieved by finishing the etching when the through holes 102 reach the lower interconnect layer. After the formation of the through holes 102 and the dummy through holes 104, a conductive material is embedded in the through holes 102 to connect the interconnect layer and the conductive material embedded in the through holes 102. Even when the conductive material is embedded in the dummy through holes 104 as well, it is possible not to connect the dummy through holes 104 to the lower interconnects electrically by the construction mentioned above.

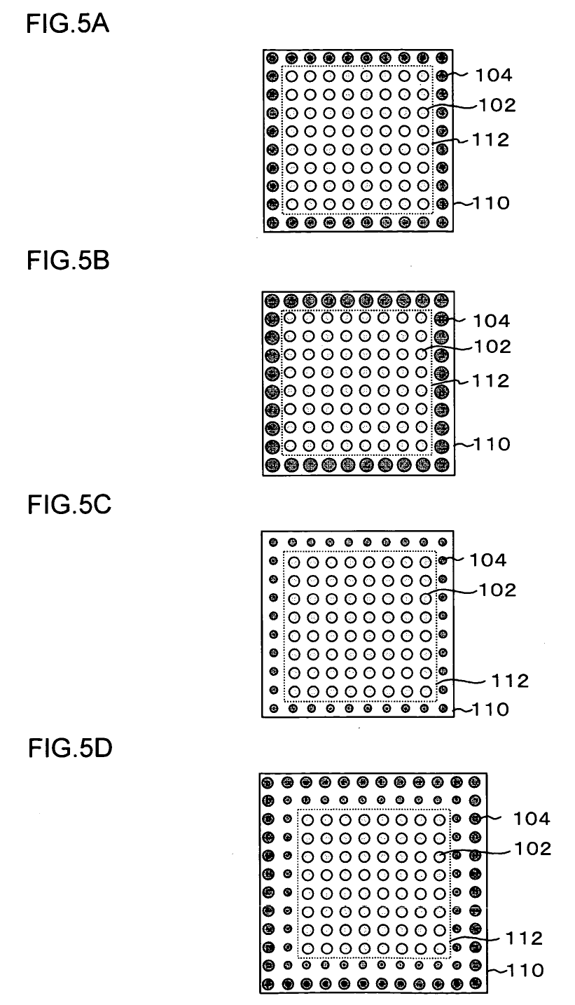

FIGS. 5A to 5D are top views showing the other examples of the arrangement pattern of the dummy through holes 104. The following explanation bases on the case where the etching rate of through holes formed in the outermost region decreases. However, the same arrangement pattern can be used even when the etching rate of through holes formed in the outermost region increases.

As shown in FIG. 5A, the dummy through holes 104 can be formed so that the opening width is nearly equal to that of the through holes 102. This will make design of a device easy since the diameter of the dummy through holes 104 can be same as that of the through holes 102. When the etching rate of the through holes formed in the outermost region of a plurality of through holes is lower than that in the center region, the construction wherein the dummy through holes are not opened to the lower interconnect layer can be achieved by finishing the etching when the through holes 102 reach the lower interconnect layer. With this, it is possible not to connect the dummy through holes 104 to the lower interconnect electrically even when a conductive material is embedded in the dummy through hole 104 when the material is embedded in the through holes 102 to connect the interconnect and the material embedded in the through hole 102, after the formation of the through holes-102 and the dummy through holes 104. Therefore, the dummy through holes 104 can be formed with no limitation on the location.

As shown in FIG. 5B, the dummy through holes 104 can be also formed so that the opening width thereof is larger than that of the through holes 102. By widening the opening width of the dummy through holes 104 like this, the reduction of the etching rate of the through holes 102 formed in the neighborhood of the dummy through holes 104 can be restrained even if the number of the dummy through holes 104 is reduced. In this case, the dummy through holes 104 is formed in a region of the interlayer dielectric film 110, where interconnect line etc. are not formed in the lower and the upper layer.

On the other hand, the dummy through holes 104 can be formed so that the opening width is smaller than that of the through holes 102 as shown in FIG. 5C. The etching rate of a through hole has a tendency to decrease with increasing the aspect ratio of the through hole typically. Therefore, the etching rate of the dummy through holes 104 can be made lower than that of the through holes 102 by forming the dummy through holes 104 with the opening width smaller than that of the through holes 102. With this, it is possible not to connect the conductive material embedded in the dummy through holes 104 and the lower interconnect electrically, even when the dummy through holes 104 is formed over the interconnect line in the lower layer. In this case, the dummy through holes 104 can be formed with no limitation of the location.

As shown in FIG. 5D, the dummy through holes 104 can be also formed with double-layered structure in the circumference of the through holes 102. In this case, the opening width of the dummy through holes 104 in the inside layer can be small, and the opening width of the dummy through holes 104 in the outer layer can be larger than that of the dummy through holes 104 in the inside layer. It is possible to prevent the dummy through holes 104 from reaching the interconnect line in the lower layer even if the opening width is made large since the etching rate in the outer layer further decreases.

Although the examples mentioned above are about only the cluster of through holes 112, the similar construction can be also applies to the dummy through holes 104 formed in the circumference of the isolated through hole 114.

Moreover, also in the case where the etching rate of a through hole formed in the outermost region increases, the ununiformity in the etching rates can be shifted to the dummy through holes 104 by forming the dummy through holes 104 in the circumference. Therefore, the ununiformity in the etching rates of the through holes 102 which contribute electric movement of a semiconductor device can be reduced.

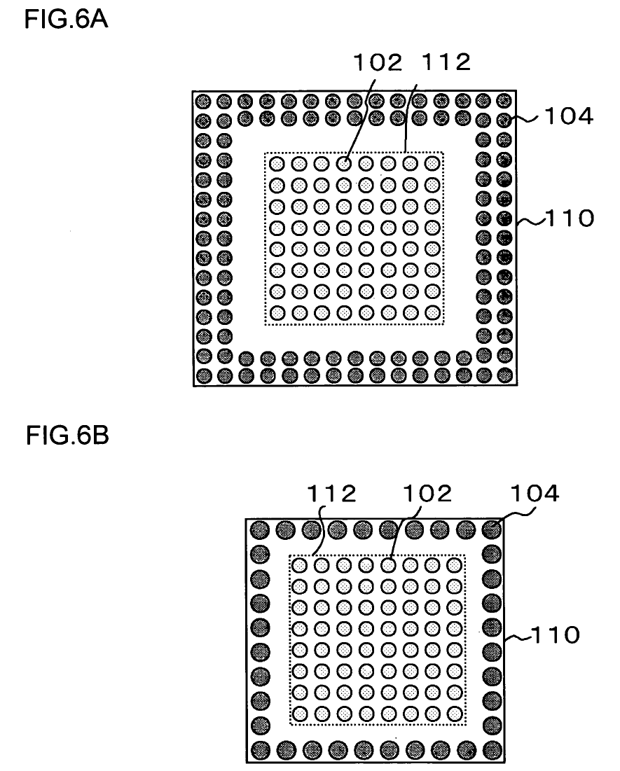

As shown in FIGS. 6A and 6B, the dummy through holes 104 can be arranged at the wider interval than the interval between the through holes 102 in the cluster, as long as the dummy through holes 104 are arranged within the predetermined distance from the through holes 102 included in the cluster of through holes 112. Even by this, the decrease or the increase in the etching rate of the through holes 102 arranged in the outermost region of the cluster of through holes 112 can be restrained. As a result, the ununiformity in the shape in the depth direction of the through holes 102 can be reduced.

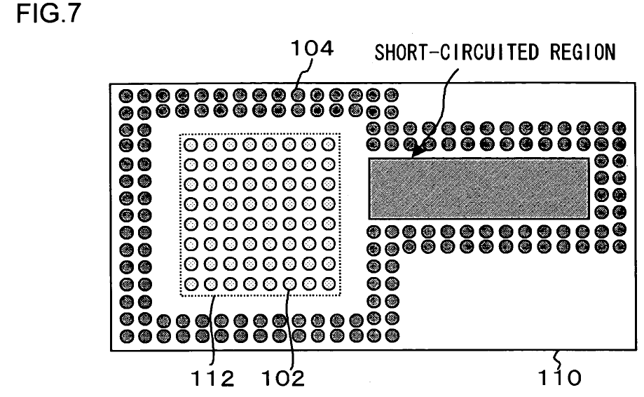

As shown in FIG. 7, the dummy through holes 104 can be arranged so as to surround all the through holes 102. Furthermore, when a short-circuited region connecting the upper and the lower interconnect layer electrically is provided near the through holes 102, the dummy through holes 104 can be also arranged so as to surround the short-circuited region. In this figure, the shaded area indicates the region where the interconnect lines are provided in both of the upper and the lower layers. Like this, in the case where a short-circuited region sandwiched by interconnect lines provided in both of the upper and the lower layers exists, the dummy through holes 104 are arranged so as to avoid this short-circuited region.

As mentioned above, the ununiformity in the etching rates of through holes can be reduced since the construction wherein each through hole is surrounded by other through hole or dummy through holes can be achieved. With this construction, the phenomenon of the decrease or the increase in the etching rate which originally occurs in through holes arranged in the outermost region of a plurality of through holes or in an isolated through hole can be shifted to the dummy through holes. As a result, the ununiformity in the etching rates of a plurality of through holes can be reduced.

### THE SECOND EMBODIMENT IN THE FIRST GROUP

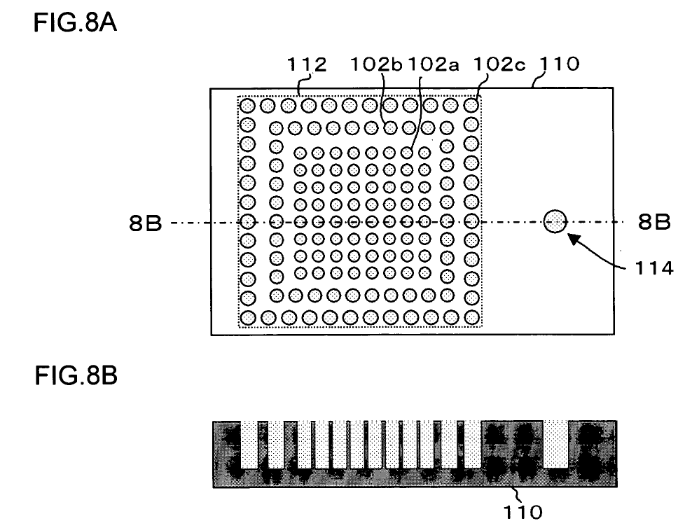

FIGS. 8A and 8B shows a construction of a semiconductor device in the second embodiment of the first group of the present invention.

In this embodiment, a dummy through hole is not formed, but the through holes 102 included in the cluster of through holes 112 are formed so that the opening width becomes wider as the location is closer to the circumference of the cluster.

For example, the through hole 102c arranged in the outermost region of the cluster of through holes 112 is formed so that the opening width is wider than that of the through hole 102b arranged in the inside. And, the through hole 102b is formed so that the opening width is wider than that of the through hole 102a arranged in the center region. Furthermore, the isolated through hole 114 is formed with a wider opening width than that of the through hole 102c arranged in the outermost region of the cluster of through holes 112.

With this, the etching rate of the isolated through hole 114, and the through holes, 102b and 102c, arranged in the outermost region of the cluster of through holes 112 can be higher than that of the through hole 102a arranged in the center region, by a micro-loading effect. As a result, the phenomenon of decrease in the etching rates of the through holes, 102b and 102c, formed in the outermost region and the isolated through hole 114 can be canceled. Therefore, the ununiformity in the etching rates of all of the through holes, 102a, 102b and 102c, included in the cluster of through holes 112, and of the isolated through hole 114 can be reduced. With this, the ununiformity in the shape in the depth direction of the plurality of through holes 102 can be reduced.

In the case where the etching rate of through holes formed in the outermost region is higher, the through hole 102 can be formed so that the opening width becomes smaller as the location is closer to the circumference. By reducing the opening width of the through holes 102 in the outermost region, the increase in the etching rate of the through holes 102 in the outermost region can be reduced. With this, the ununiformity in the etching rates of the plurality of through holes 102 can be reduced.

### EXAMPLE IN THE FIRST GROUP

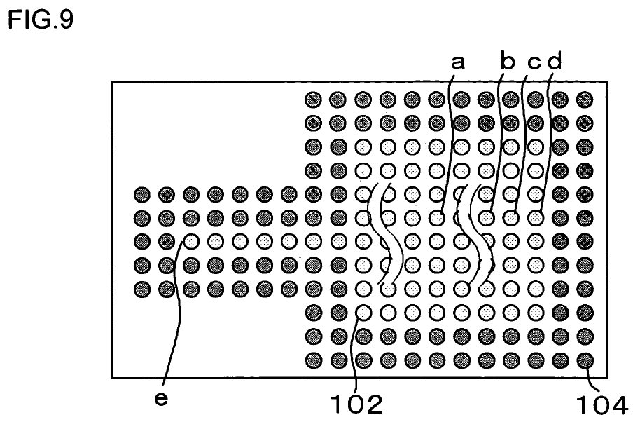

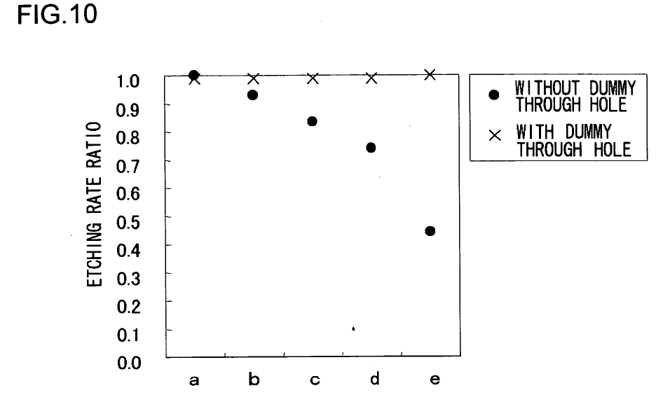

FIG. 9 shows a pattern where the dummy through holes 104 are formed in the circumference of the cluster of a plurality of through holes 102.

The through holes 102 and the dummy through holes 104, which constituted the pattern shown in FIG. 9, were formed by etching, after the formation of the dielectric film 110 made of SiOC on a silicon substrate by a CVD method. Both diameters of the through holes 102 and the dummy through holes 104 were 0.2 μm and the interval was 1 μm. The etching conditions were: a gas flow rate of Ar/CF₄/CH₂F₂/N₂=500/30/10/90 sccm, a pressure of 50 mTorr, and a RF power of 1300 W.

FIG. 10 shows the result of the example. When the dummy through holes 104 were not formed, the etching rates of the through hole c and the through hole d arranged in the outermost region of the cluster of through holes formed in a matrix and the through hole e formed in a row decreased. On the other hand, the decrease in the etching rate of the through hole c, the through hole d and the through hole e could be restrained by forming the dummy through holes 104 in the circumference of these through holes. As a result, the etching rates of all of the through holes 102 could be almost uniform. With this, the ununiformity in the shape in the depth direction of the plurality of through holes, a, b, c, d and e could be reduced, and the through holes could be formed almost equally.

The decrease in the etching rate of an isolated through hole could be also restrained by forming the dummy through holes 104 in the circumference of the isolated hole, although it is not shown in FIG. 9. Therefore, the etching rate of the isolated through holes could be almost equal to that of the through holes a and the through hole b formed in the center region of the cluster of through holes, and the ununiformity in the shape in the depth direction could be reduced.

Although the mechanism by which the ununiformity in the etching rates of the through holes 102 can be reduced by forming the dummy through holes 104 in circumference of the through holes 102 as described above is not clear, the following conjecture can be made.

“OYO BUTURI” (vol. 70, No. 4, pp. 387-397, 2001) shows that a polymer layer is formed on an etched surface during etching of SiO₂ film by a fluorocarbon plasma, and the thickness of the polymer layer depends on the amount of the incident species CFₓ activated for etching and the amount of the oxygen O contained in the film. Considering this result, it can be conjectured that a thicker polymer layer is formed on SiOC film compared with on SiO₂ film since SiOC has a smaller component ratio of oxygen, and contains carbon C.

The amount of the activated species CFx incident from the plasma does not depend on the pattern. On the other hand, the reaction products, which have a polymer removal action, are formed by etching gas during the etching of the dielectric film. The reaction products by etching gas here are a compound of Si with F, a compound of C with F and a compound of O. The reaction products by etching gas are released from the etched region on the surface, and stays over the patterns. Therefore, it is conjectured that the density of the reaction products by etching gas is larger at the center of a cluster of patterns, and is smaller in the outermost of the cluster of patterns and at an isolated pattern. As a result, a thicker polymer layer is formed in the outermost of the cluster of patterns and at the isolated pattern compared with at the center of the cluster of patterns. It is considered that the effective range of the reaction product by etching gas is within 100 μm from the etched region approximately. Therefore, it can be conjectured that the reaction products that have an influence on the through holes 102 formed in the outermost region can be increased by forming the dummy through holes 104 in the circumference of the through holes 102. As a result, the difference in etching rates of the through holes 102 formed in the outermost region and the center region can be reduced.

The present invention belonging to the first group has been explained by describing a representative embodiment and a example. The embodiment and the example are illustrative in nature and it is obvious to those skilled in the art that numerous modifications and variations in constituting elements and processes are possible and are within the scope of the present invention.

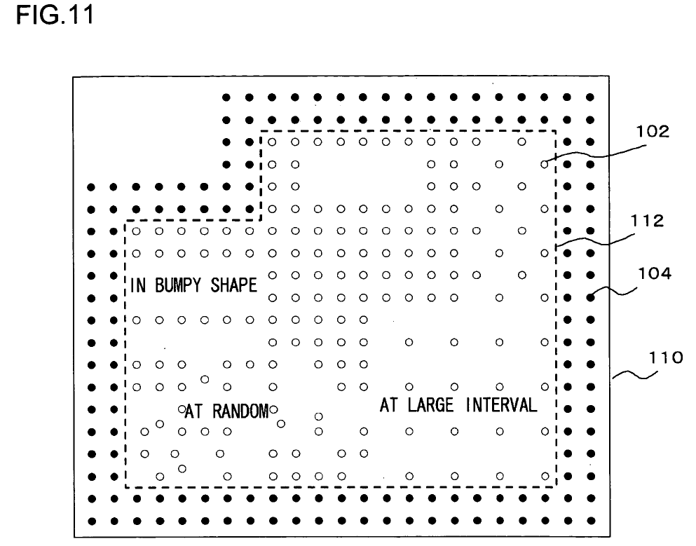

The examples of the plurality of through holes 102 arranged in a matrix were shown in the first embodiment. The plurality of through holes 102,can be also arranged in such patterns as shown in FIGS. 11 to 13. In these cases, the dummy through holes 104 can constitute the construction shown in FIGS. 11 to 14. Each figure will be described below.

The region including the plurality of through holes 102 can include the regions where the through holes arranged at random, at large intervals or in bumpy shape, as shown in FIG. 11. In this case, the dummy through holes 104 can be arranged in the circumference of these regions.

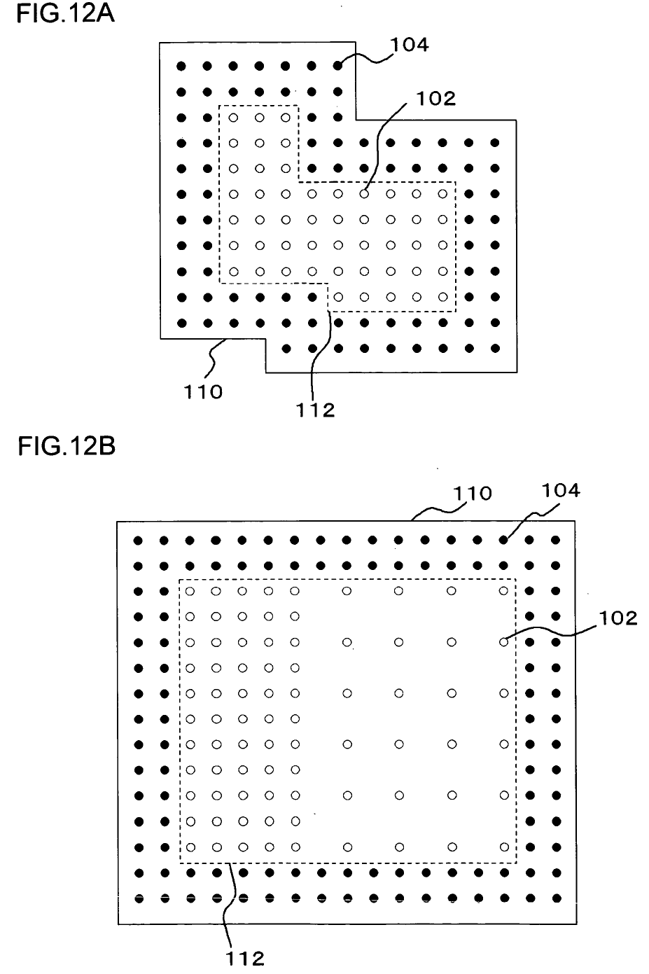

The through holes 102 can be also arranged in a shape other than square, as shown in FIG. 12A. The dummy through holes 104 can be arranged in the circumference of the plurality of through holes 102 in this case as well. Furthermore, the through holes 102 can be also arranged at the interval which varies depending on the location as shown in FIG. 12B.

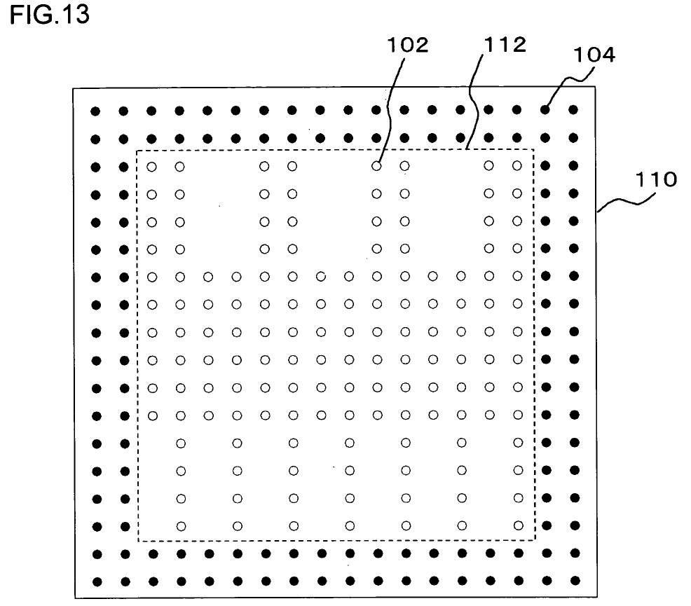

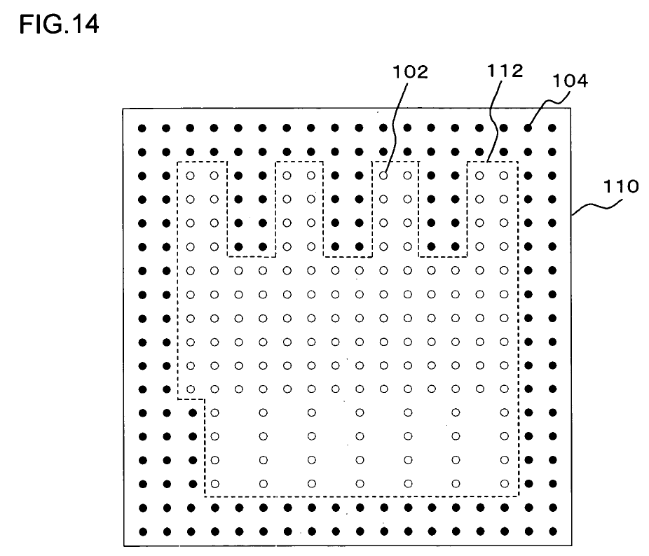

The plurality of through holes 102 can be also arranged in a comb row as shown in FIG. 13. In the case of the arrangement of the through holes 102 in a comb row like this, the dummy through holes 104 can be arranged between the comb teeth when the interval of the teeth is wide as shown in FIG. 14. With this, the construction where the dummy through holes 104 is provided in the circumference of the cluster of through holes 112 can be obtained.

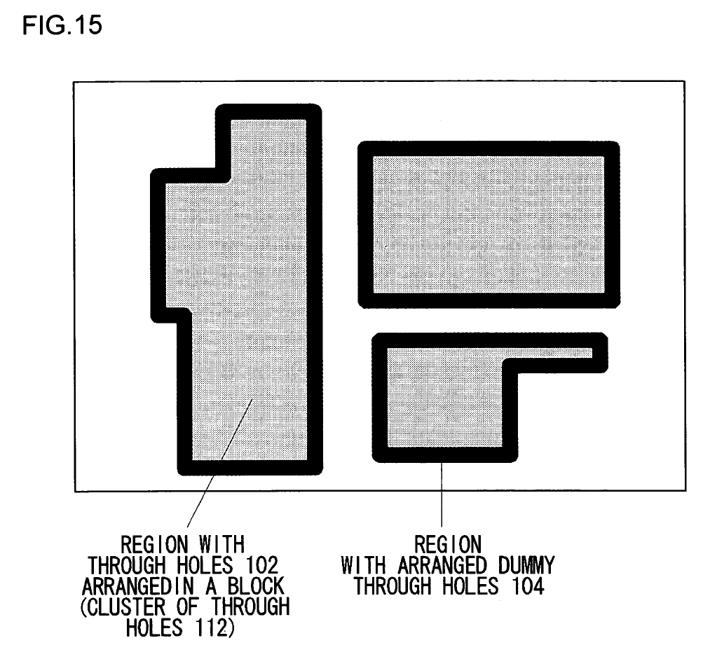

FIG. 15 schematically shows a part of an overall construction of a circuit wherein some clusters of through holes 112 is formed. As shown in this figure, the dummy through holes 104 are formed along the circumferences of the clusters of through holes 112 consisting of the through holes 102. With this, even if the ununiformity in the etching rates arises in the circumference of the cluster of through holes, it arises only in the dummy through holes 104. As a result, the ununiformity in the etching rates of a plurality of through holes that contribute to electric movement of a semiconductor device can be reduced.

Although the examples about through holes were shown in the embodiment described above, the same can be also applied to a trench for interconnect line. The ununiformity in the etching rates depending on the pattern arrangement of a plurality of trenches for interconnect lines can be reduced by forming dummy trenches or dummy through holes in circumference of the trench for interconnect line formed in the outermost region or in isolation. The construction where dummy trenches are formed in the circumference of a plurality of through holes is also effective.

### THE SECOND GROUP

### REFERENCE EXPERIMENT

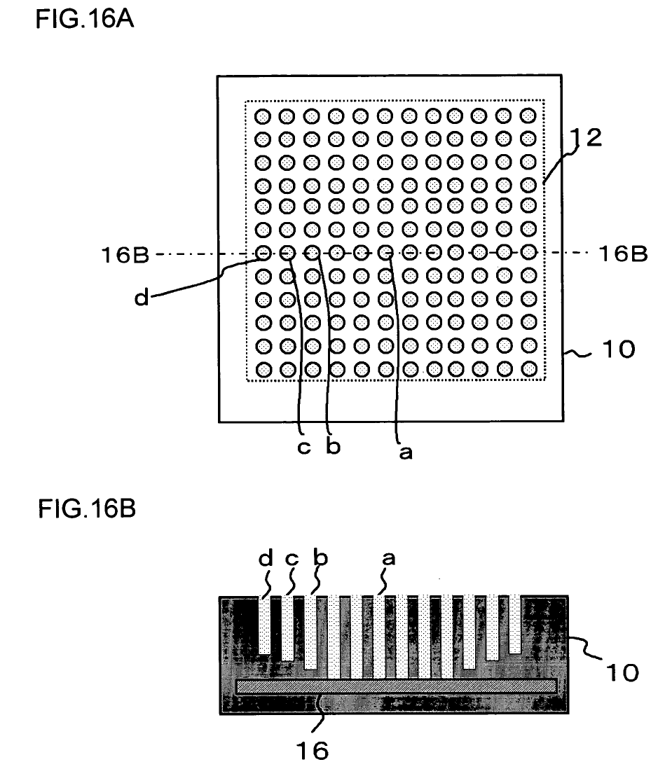

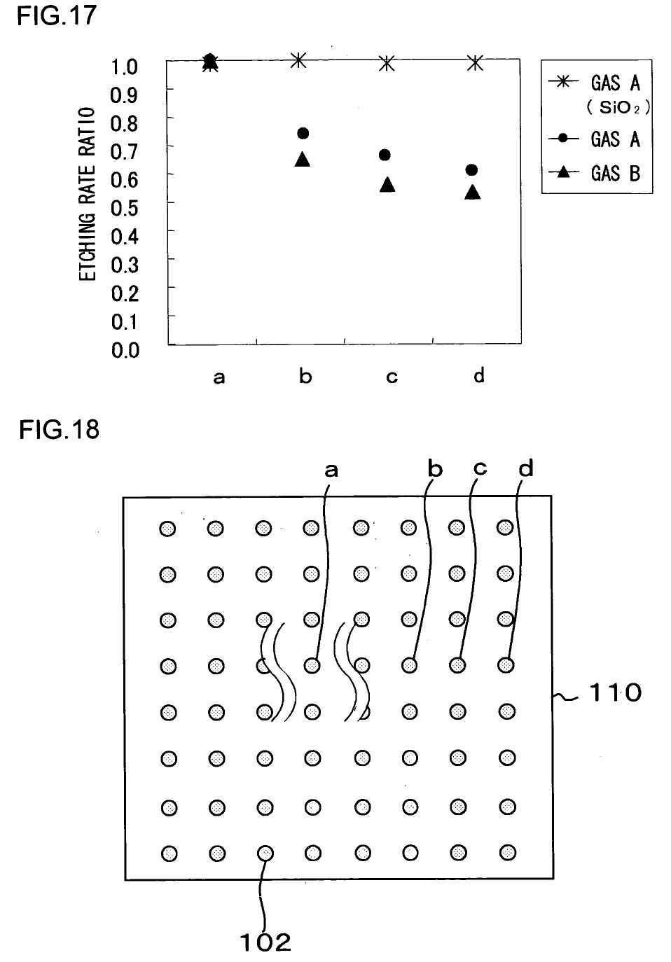

First, a result of a reference experiment about etching of through holes arranged in the matrix shown in FIG. 16A will be described. FIG. 16B is an example of a cross sectional view taken in the line of 16B-16B of FIG. 16A. FIG. 17 shows etching rates when the through holes in the patterns shown in FIG. 16A in some kinds of film were etched by some kinds of etching gas, that is:
(1) SiO₂ was used for the interlayer dielectric film, and Gas A was used as the etching gas;
(2) SiOC was used for the interlayer dielectric film, and Gas A was used as the etching gas; and
(3) SIOC was used for the interlayer dielectric film, and Gas B was used as the etching gas.

The conditions of Gas A and Gas B were: the gas containing Ar, CF₄, CH₂F₂ and N₂, a N₂ content of 8% by gas flow ratio, a pressure of 50 mTorr and an RF power of 1300 W; and the gas containing Ar, C₄F₈ and N₂, a N₂ content of 9% by gas flow ratio, a pressure of 50 mTorr and an RF power of 1300 W, respectively.

The diameter of the through hole was 0.2 μm. When SiO₂ was used for the interlayer dielectric film, the difference in the etching rates depending on the state of arrangement of through holes did not arise.

On the other hand, when SiOC was used for the interlayer dielectric film, the etching rate of the through hole b decreased by about 30% compared with that of the through hole a, when CF₄ and CH₂F₂ were used as the etching gas. In this case, the etching rates of the through hole c and the through hole d decreased by 30% to 40% compared with that of the through hole a. Furthermore, when C₄F₈ was used as the etching gas, the etching rate of the through hole b also decreased by 30% or more compared with that of the through hole a. In this case, the etching rates of the through hole c and the through hole d decreased by about 50% compared with that of the through hole a. The results show that the ununiformity in etching rates of through holes depending on the state of arrangement arises when SiOC film is etched by using the gas such as CF₄, CH₂F₂ and C₄F₈.

### THE FIRST EXAMPLE IN THE SECOND GROUP

Next, the examples are explained. Although SIOC film was used as a material of the interlayer dielectric film in the following examples, SiOCN film and MSQ film can be also used. SiOC film is sometimes written with SiOCH film, and it usually contains Si, O, C and H as the composition elements.

In the following example, the case that a plurality of through holes is formed in the interlayer dielectric film by using an etching gas containing a fluorocarbon gas and a nitrogenous gas will-be described.

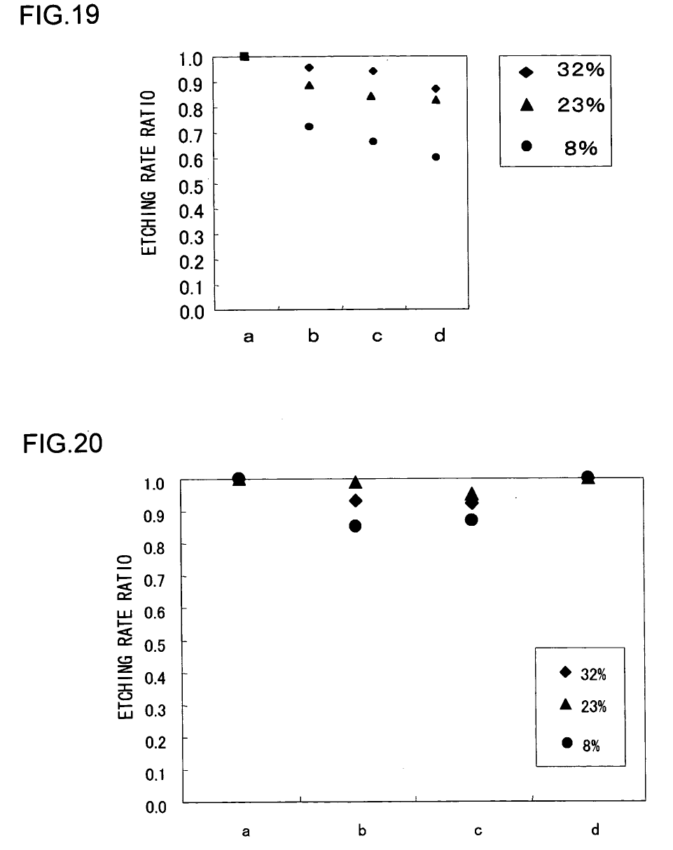

FIG. 18 is a top view of the interlayer dielectric film 110 where the plurality of through holes 102 was formed. SiOC film was used for the interlayer dielectric film 110.

The interlayer dielectric film 110 made of SiOC was formed on a silicon substrate by a CVD method. After that, the through holes a to d in the pattern shown in FIG. 18 were formed by using the etching gas containing CF₄ and CH₂F₂ as gases of fluorocarbon, and Ar as a dilution gas. The diameter of the through hole here was 0.2 μm, and the interval was 1 μm. N₂ gas was used as the nitrogenous gas.

The N₂ content in the etching gas was 8%, 23% or 32% by gas flow ratio. All the etching was performed under the condition of a pressure of 50 mTorr and an RF power of 1300 W.

FIG. 19 shows the result of the example. In this figure, the etching rate of the through hole a was set to 1.0. When the N₂ content in the etching gas was about 8% by gas flow ratio, the etching rates of the through holes c and d formed in the outermost region of the plurality of through holes 102 arranged in a matrix decreased by 30% or more, compared with that of the through hole a formed in the center region. The etching rate of the through hole b arranged in the third row from the outermost row in the matrix consisting of the through holes 102 also decreased by about 30% compared with that of the through hole a. As a result of several experiments in the similar range of the N₂ content, it was shown that the etching rates of the through holes b, c and d decreased by about 30% to 40% compared with that of the through hole a in any case.

On the other hand, when the N₂ content in the etching gas was 23% by gas flow ratio, the decrease in the etching rate of the through holes b, c and d could be restrained within 20% compared with that of the through hole a. The several experiments in the similar range of the N₂ content showed the result where the decrease in the etching rates of the through holes b, c and d could be restrained within 20% compared with that of the through hole a as well.

Furthermore, when the N₂ content in the etching gas was 32% by gas flow ratio, the decrease in the etching rates of the through holes b, c and d could be restrained by nearly 10% compared with that of the through hole a.

As described above, it was proved that the differences in dimension conversion in the depth direction induced by etching could be reduced regardless of the state of arrangement of a plurality of through holes by setting the N₂ content in the etching gas to 23% or more by gas flow ratio.

It was confirmed that the difference in dimension conversion in the depth direction induced by etching could be also reduced in through holes formed at the end of a row consisting of a plurality of through holes and a through hole formed in isolation, by using etching gas containing N₂ with a gas flow ratio of 23% or more. With this, regardless of the state of arrangement of through holes, the ununiformity in the etching rates can be reduced enough for an etching residue or thinned under layer film not to matter effectively. As a result, the yield rate can be improved.

### THE SECOND EXAMPLE IN THE SECOND GROUP

As same as the first example, the interlayer dielectric film 110 made of SiOC was formed on a silicon substrate by a CVD method. After that, the through holes a to d in the pattern shown in FIG. 18 were form ed by using the etching gas containing C₄F₈ as a gas of fluorocarbon, and Ar as a dilution gas. The diameter of the through hole here was 0.2 μm, and the interval was 1 μm. N₂ was used as the nitrogenous gas. The N₂ content in the etching gas was 23% by gas flow ratio. All the etching was performed under the condition of a pressure of 50 mTorr and an RF power of 1300 W. In this case, the decrease in the etching rates of through holes b, c and d could be restrained as well.

### THE THIRD EXAMPLE IN THE SECOND GROUP

As same as the first example, the interlayer dielectric film 110 made of SIOC was formed on a silicon substrate by a CVD method. After that, the through holes a to d in the pattern shown in FIG. 18 were formed by using the etching gas I containing CF₄ and CH₂F₂ as gases of fluorocarbon, and the etching gas II containing C₄F₆ and CH₂F₂ as gases of fluorocarbon, step by step. The diameter of the through hole here was 0.2 μm, and the interval was 1 μm. Ar was used as a dilution gas, and N₂ was used as the nitrogenous gas in both etching gases. The N₂ content in the etching gas II were always 14% by gas flow ratio.

In this example, the etching rates of through holes formed by etching were measured when the N₂ content in the etching gas I was 8%, 23% and 32% by gas flow ratio. All the etching was performed under the condition of a pressure of 50 mTorr and an RF power of 1300 W.

When the N₂ content in the etching gas I was 8%, the ratio of processing times for the etching gas I and the etching gas II was set to 1.0:5.0. When the N₂ content in the etching gas I was 23%, the ratio of processing times for the etching gas I and the etching gas II was set to 1.0:2.3. When the N₂ content in the etching gas I is 32%, the-ratio of processing times for the etching gas I and the etching gas II was set to 1.0:1.3. The ratio 1.0 here corresponds to about 30 seconds.

FIG. 20 shows the results of the example. In this figure, the etching rate ratio 1.0 corresponds to the etching rate of the through hole d that has a largest etching rate. By forming through holes step by step by using the etching gas I and II as explained above, the ununiformity in the etching rates of the plurality of through holes could be restrained within 15%, in all cases of the N₂ contents of 8%, 23% and 32%.

In the example of the N₂ content in the etching gas I of 23% or more, the ununiformity in the etching rates could be restrained within 10%. The ununiformity could be achieved to the value comparable to the result of the N₂ content of 32% in the first example.

The processing time of each etching using the etching gas I and II can be properly fixed according to the kind of fluorocarbon gas and nitrogenous gas contained in the etching gas and their contents etc. It is possible to further reduce the ununiformity in etching rates by adjusting this processing time.

It was confirmed that the difference of dimension conversion in the depth direction in isolated through holes surrounded by no other through hole could be also restrained by using the etching gas I and II step by step.

Furthermore, the through holes a to d in the pattern shown in FIG. 18 were formed by using the etching gas containing C₄F₈ as well as the second example described above. N₂ content in the etching gas was about 28% by gas flow ratio. The diameter of the through hole was 0.2 μm, and the interval was 1 μm. The result shows that the etching rate of through holes arranged at the edge of a block including through holes can be increased as well as the case of using C₄F₆ as a gas of fluorocarbon. The same applies to a through hole arranged in isolation.

In this example, dry etching can be performed step by step, by using the first etching gas containing a fluorocarbon gas such as C₄F₈ and a nitrogenous gas, and the second etching gas containing the same kinds of gas as the first etching gas with a higher content of nitrogenous gas, in the step to form a plurality of through holes. With this, the difference of dimension conversion in the depth direction induced by etching can be reduced, and the ununiformity in the shape in the depth direction in through holes depending on the state of arrangement can be reduced.

The present invention belonging to the second group has been explained by describing representative examples. The examples are illustrative in nature and it is obvious to those skilled in the art that numerous modifications and variations in constituting elements and processes are possible and are within the scope of the present invention.

Although the examples about the through hole were described above, the same can be also applied to trenches for interconnect lines. The ununiformity in etching rates of a plurality of trenches depending on the state of arrangement can be reduced by using the etching gas which has a composition described in the above example.

### THE THIRD GROUP

### REFERENCE EXPERIMENT

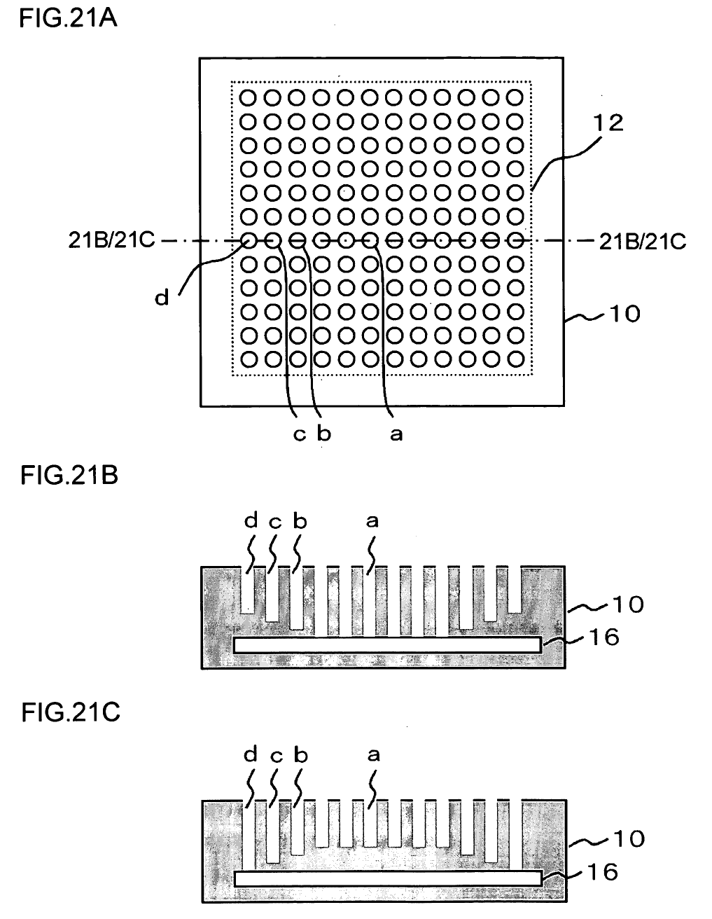

First, a result of a reference experiment will be shown. FIG. 21A shows a through hole pattern used for the reference experiment:. SiOC film was used for the interlayer dielectric film. SiOC film is sometimes written with SiOCH film, and it usually contains Si, O, C and H as the composition elements. FIGS. 21B and 21C show examples of cross sectional views taken in the line 21B/21C-21B/21C of FIG. 21A. Table 1 shows etching rates when the through holes in the pattern shown in FIG. 21A in SiOC film were formed by using etching gases containing various kinds of fluorocarbon gas and the gas flow rate respectively. In this table, an etching rate of 1 corresponds to the etching rate of the through hole a.

The etching conditions A, B, C and D were respectively:
a gas flow rate of Ar/CF₄/N₂=500/8/125 sccm, a pressure of 50 mTorr, and a RF power of 1300 W;
a gas flow rate of Ar/CF₄/N₂=500/40/125 sccm, a pressure of 50 mTorr, and a RF power of 1300 W;
a gas flow rate of Ar/C₄F₈/N₂=500/8/125 sccm, a pressure of 50 mTorr, and a RF of power 1300 W; and
a gas flow rate of Ar/C₄F₈/N₂=500/10/125 sccm, a pressure of 50 mTorr, and a RF power of 1300 W.

The diameter of the through hole was 0.2 μm. In the condition A wherein CF₄ was used as a fluorocarbon gas, there was no difference between the etching rates of the through hole d formed in the outermost region and the through hole a formed in the center region. On the other hand, the etching rate in the outermost region became higher in the condition B where the gas flow rate of CF₄ was increased. In the condition C wherein C₄F₈ was used as a fluorocarbon gas and the gas flow rate was same as that in the condition A, the etching rate at the outermost became lower. However the etching rate at the outermost became higher in the condition D where the gas flow rate of C₄F₈ was slightly increased.

As described above, the results revealed that the etching rate at the outermost increased with increasing the flow rate of a fluorocarbon gas. This tendency became remarkable in the case of C₄F₈.

If the slight variation of the gas flow rate induces a significant increase in the etching rate like this, some problems will occur. For example, over etching will be excessively performed against interconnect line formed under the region where the etching rate is high, or residues will remain in the through hole in the region where the etching rate is low. As a result, the dimension conversion in the depth direction will differ from the original design due to etching, and this will induce a low yield rate.

TABLE 1

| | CONDITION OF | | | |
|---|---|---|---|---|
| | FLUOROCARBON GAS | | ETCHING RATE | |
| | KIND OF GAS | GAS FLOW RATE | a | d |
| CONDITION | CF₄ | 8 sccm | 1 | 1.0 |
| A | | | | |
| CONDITION | CF₄ | 40 sccm | 1 | 1.4 |
| B | | | | |
| CONDITION | C₄F₈ | 8 sccm | 1 | 0.8 |
| C | | | | |
| CONDITION | C₄F₈ | 10 sccm | 1 | 1.9 |
| D | | | | |

### THE FIRST EXAMPLE IN THE THIRD GROUP

Next, some examples of applications of the third group of the present invention will be explained referring to figures.

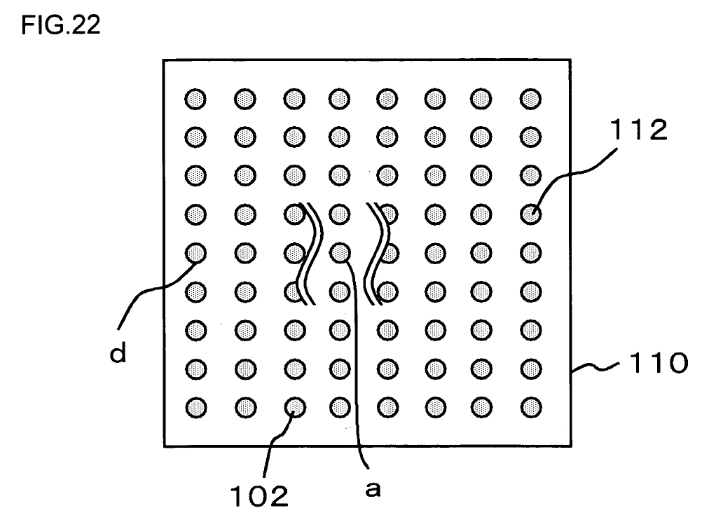

FIG. 22 is a top view of the dielectric film 110 where the plurality of through holes 102 was formed. Here, SIOC film was used for the interlayer dielectric film 110.

The interlayer dielectric film 110 made of SIOC was formed on a silicon substrate by a CVD method. After that, the pattern where through holes-were arranged in the matrix with 154 rows and 154 columns as shown in FIG. 22 was formed by selective etching, i.e., reactive ion etching, of the interlayer dielectric film 110. The diameter of the through hole was 0.2 μm, and the interval between the adjoining through holes was 1 μm. The gas flow rate of C₄F₈ contained in the etching gas was 1 sccm, 2 sccm, 4 sccm, 6 sccm, 8 sccm, 10 sccm or 12 sccm. The etching conditions except for the gas flow rate of C₄F₈ were: a gas flow rate of Ar/N₂=500/125 sccm, a pressure of 50 mTorr and an RF power of 1300 W. The etching gas contained no oxygen substantially.

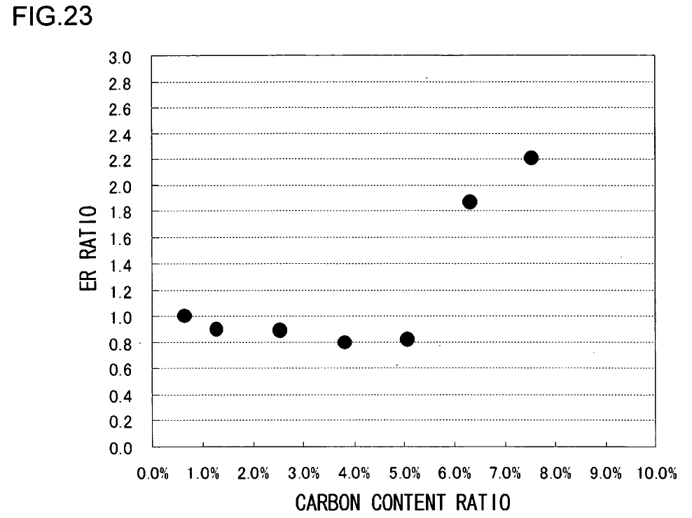

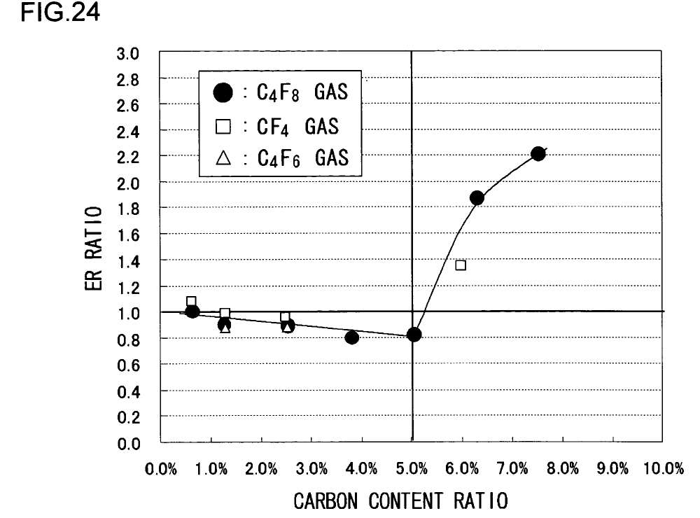

FIG. 23 shows the relations between the etching rate ratio of the through hole d to the through hole a, which are shown in FIG. 22, and the carbon content ratio. The carbon content ratio indicated on the horizontal axis in FIG. 23 was defined by:
Carbon content ratio=X×(Qc/Q)×100 (1)
where X is a carbon component ratio X in a fluorocarbon gas represented by C_{X}F_{Y}. In this example, X became “4” since C₄F₈ gas was used. Q is a total flow rate of the etching gas, and Qc is a gas flow rate of fluorocarbon C_{X}F_{Y}.

The vertical axis indicates the etching rate ratio of the through hole d at the edge of the array pattern of through holes to the through hole a at the center.

FIG. 23 shows that:
(i) in the condition range with a carbon content ratio up to 5%, the difference between the etching rates of the through hole d and that of the through hole a was low, the etching rate of the through hole d was lower than that of the through hole a, and the etching rate ratio-of the through hole d formed at the edge decreased with increasing the carbon content ratio; and
(ii) in the condition range with a carbon content ratio above 5%, the etching rate of the through hole d was higher than that of the through hole a, and the etching rate ratio of the through hole d formed at the edge increased with increasing the carbon content ratio.

These results proved that differences in dimension conversion in the depth direction induced by etching could be reduced by setting the carbon content ratio in the etching gas to 5% or less, regardless of the variation in the carbon content ratio during the etching process or the state of arrangement of the plurality of through holes.

As shown in FIG. 23, the difference in etching rates at the edge and at the center of a block-shaped pattern including through holes can be restrained within 20%, by setting the carbon content ratio to 5% or less. Furthermore, etching can be performed steadily even when the carbon content ratio varies during the etching process, since the dependence of etching rate on the carbon content ratio is small when the carbon content ratio is 5% or less. With this, the ununiformity in the shape of through holes can be restrained effectively, and a yield rate can be improved.

In addition, it was confirmed that a difference in dimension conversion in the depth direction induced by etching could be reduced also in the case of the through holes arranged at the end of the row consisting of a plurality of through holes, and in the case of the isolated through hole surrounded by no other hole, by setting the carbon content ratio to 5% or less.

Furthermore, when CF₄ or C₄F₆ gas was used as a fluorocarbon gas, it was confirmed that the variation of the carbon content ratio resulted in the same tendency as the case of C₄F₈ as shown in FIG. 24.

### THE SECOND EXAMPLE IN THE THIRD GROUP

The interlayer dielectric film 110 made of SiOC was formed on a Silicon substrate by a CVD method, as well as the first example. After that, the through holes in the pattern shown in FIG. 22 were formed by the first dry etching using a etching gas containing C₄F₈, and the second dry etching using a etching gas with a carbon content ratio lower than that in the gas used in the first etching, step by step. The diameter of the through hole was 0.2 μm, and the interval between the adjacent through holes was 1 μm. The dry etching was reactive ion etching (RIE). The following conditions 1 to 4 were applied in combination to the first and the second dry etching. The definition of the carbon content ratio was the same as the first example.
Condition 1: a gas flow rate of Ar/C₄F₈/N₂=500/12/125 sccm, a pressure of 50 mTorr, an RF power of 1300 W, and a carbon content ratio of 7.5%
Condition 2: a gas flow rate of Ar/C₄F₈/N₂=500/10/125 sccm, a pressure of 50 mTorr, an RF power of 1300 W, and a carbon content ratio of 6.3%
Condition 3: a gas flow rate of Ar/C₄F₈/N₂=500/8/125 sccm, a pressure of 50 mTorr, an RF power of 1300 W, and a carbon content ratio of 5.1%
Condition 4: a gas flow rate of Ar/C₄F₈/N₂=500/6/125 sccm, a pressure of 50 mTorr, an RF power of 1300 W, and a carbon content ratio of 3.8%

In this example, the etching rates were measured when the through holes were formed under four conditions:
Condition 1+Condition 3, Condition 2+Condition 3, Condition 1+Condition 4, and Condition 2+Condition 4.

In the case of Condition 1+Condition 3, the processing time of each etching step was calculated so that the ratio of the amount of the first and the second dry etchings was 0.39:1.0. In the case of Condition 2+Condition 3, the processing time of each etching step was calculated so that the ratio of the amount of the first and the second dry etchings was 0.38:1.0. In the case of Condition 1+Condition 4, the processing time of each etching step was calculated so that the ratio of the amount of the first and the second dry etchings was 0.31:1.0. In the case of Condition 2+Condition 4, processing time of each etching step was calculated so that the ratio of the amount of the first and the second dry etchings was 0.26:1.0.

Table 2 shows the result. In this Table; the etching rate of 1.0 corresponds to that of the through hole a formed in the center region of the cluster of through holes 112. As shown in Table 2, the difference in etching rates of the plurality of through holes could be reduced by forming through holes by the first dry etching and the second dry etching, step by step.

TABLE 2

| THE FIRST DRY ETCHING | | | THE SECOND DRY ETCHING | | | |
|---|---|---|---|---|---|---|
| CONDI- | CARBON CONTENT | COEFFI- | CONDI- | CARBON CONTENT | COEFFI- | |
| TION | RATIO | CIENT | TION | RATIO | CIENT | ER RATIO |
| 1 | 7.5% | 0.39 | 3 | 5.1% | 1 | 1.0 |
| 2 | 6.3% | 0.38 | 3 | 5.1% | 1 | 1.0 |
| 1 | 7.5% | 0.31 | 4 | 3.8% | 1 | 1.0 |
| 2 | 6.3% | 0.26 | 4 | 3.8% | 1 | 1.0 |

The result shows that the ununiformity in the shape in the depth direction of through holes depending on the state of arrangement of the through holes can be reduced by the combination of the first and the second dry etching since a plurality of dry etching processes with various carbon content ratios is introduced. It also becomes possible that the processing time of dry etching is shortened. Furthermore, it becomes possible that the dependence of the etching rate on the location of the through hole can be restrained stably with decreasing the damage to SiOC film, by using such inert gas as Ar or such gas as N₂ and NH₃ in the etching gas.

The present invention belonging to the third group has been explained by describing representative examples. The examples are illustrative in nature and it is obvious to those skilled in the art that numerous modifications and variations in constituting elements and processes are possible and are within the scope of the present invention.

For example, the present invention can be applied to a process to form trenches for interconnect lines, although the examples about through holes were explained above. The difference in etching rates of a plurality of trenches for interconnect lines depending on the state of arrangement can be reduced by using etching gases with the composition described in the above examples.

In addition, SiCN, SiC or MSQ film can be also used as the interlayer dielectric film, although SIOC film was used in the examples explained above. SiC and SiCN can be formed by a CVD method or a spin coat method. MSQ can be formed by a spin coat method.

Furthermore, the etching gas containing several kinds of fluorocarbon compound gas can be used, although C₄F₈, CF₄ or C₄F₆ was used alone as the fluorocarbon gas in the example explained above. In this case, the carbon component ratio X in above equation (1) can be a mean value in consideration of mol fraction, given by:
Xav=Σ(mi×Xi)
where mi is a mol fraction of a fluorocarbon component i, and Xi is a carbon component ratio in a fluorocarbon component i.

1. A semiconductor device comprising:
a dielectric film;
a plurality of concave patterns formed in the dielectric film; and
a plurality of dummy concave patterns formed in the dielectric film, and arranged in circumference of the plurality of concave patterns.

2. The semiconductor device according to claim 1, wherein the plurality of concave patterns is arranged in a block, and the plurality of dummy concave patterns is arranged along outermost regions of the plurality of concave patterns.

3. The semiconductor device according to claim 1, wherein the plurality of dummy concave patterns is formed more shallowly than the plurality of concave patterns.

4. The semiconductor device according to claim 1, wherein the plurality of dummy concave patterns is formed so that an aspect ratio of the plurality of dummy concave patterns is smaller than that of the plurality of concave patterns.

5. A semiconductor device comprising:
a dielectric film; and
a plurality of concave patterns formed in the dielectric film, wherein the plurality of concave patterns is formed so that an opening width of the concave pattern surrounded by no other concave pattern is different from that of the concave pattern surrounded by other concave patterns.

6. A manufacturing method of a semiconductor device comprising:
forming a dielectric film; and
forming a plurality of concave patterns and a plurality of dummy concave patterns in the dielectric film, wherein
the plurality of dummy concave patterns is formed in circumference of the plurality of concave patterns when the plurality of concave patterns and the plurality of dummy concave patterns are formed.

7. The manufacturing method according to claim 6, wherein the plurality of concave patterns is formed in a block, and the plurality of dummy concave patterns is formed along an outermost region of the plurality of concave patterns when the plurality of concave patterns and the plurality of dummy concave patterns are formed.

8. A manufacturing method of a semiconductor device comprising:
forming a dielectric film; and
forming a plurality of concave patterns in the dielectric film, wherein
the plurality of concave patterns is formed so that an opening width of the concave pattern surrounded by no other concave pattern is different from that of the concave pattern surrounded by other concave patterns, when the plurality of concave patterns is formed.

9. A manufacturing method of a semiconductor device comprising:
forming a dielectric film containing Si, O and C at least; and
forming a plurality of concave patterns in the dielectric film by dry etching using a etching gas containing a nitrogenous gas, wherein a content of the nitrogenous gas in the etching gas is 23% or more by gas flow ratio.

10. The manufacturing method of a semiconductor device according to claim 9, wherein the nitrogenous gas is N₂.

11. The manufacturing method of a semiconductor device according to claim 9, wherein the etching gas contains C₄F₆.

12. A manufacturing method of a semiconductor device comprising:
forming a dielectric film containing Si, O and C at least; and
forming a plurality of concave patterns in the dielectric film by dry etching using a first etching gas containing C₄F₆.

13. The manufacturing method of a semiconductor device according to claim 12 further comprising:
dry etching using a second etching gas containing one or more gases of fluorocarbon selected from CH₂F₂, CF₄ and C₄F₈, wherein
the dry etching using the first etching gas is performed before or after the dry etching using the second etching gas.

14. The manufacturing method of a semiconductor device according to claim 9, wherein the dielectric film is SiOC film.

15. The manufacturing method of a semiconductor device according to claim 12, wherein the dielectric film is SiOC film.

16. A manufacturing method of a semiconductor device comprising:
forming a dielectric film containing Si, O and C; and
forming a plurality of concave patterns in the dielectric film by dry etching using an etching gas containing a fluorocarbon, wherein
a carbon content ratio in the etching gas, p(%), defined by
p=X×(Qc/Q)×100
where X is a carbon component ratio in a fluorocarbon, Q is a total flow rate of the etching gas, and Qc is a flow rate of a fluorocarbon gas, is 5% or less.

17. A manufacturing method of a semiconductor device comprising:
forming a dielectric film containing Si, O and C; and
forming a plurality of concave patterns in the dielectric film, wherein
forming a plurality of concave patterns comprises a first dry etching using a first etching gas containing a fluorocarbon and a second dry etching using a second etching gas containing a fluorocarbon, and a carbon content ratio, p(%), defined by
p=X×(Qc/Q)×100
where X is a carbon component ratio in a fluorocarbon, Q is a total flow rate of the etching gas, and Qc is a flow of a fluorocarbon gas, in either the first etching gas or the second etching gas is less than that in another.

18. The manufacturing method of a semiconductor device according to claim 17, wherein the carbon content ratio p(%) in the second etching gas is 5% or less, and the carbon content ratio p(%) in the first etching gas is more than 5%.

19. The manufacturing method of a semiconductor device according to claim 16, wherein the fluorocarbon used to form the plurality of concave patterns contains C₄F₈.

20. The manufacturing method of a semiconductor device according to claim 17, wherein the fluorocarbon used to form the plurality of concave patterns contains C₄F₈.

21. The manufacturing method of a semiconductor device according to claim 16, wherein the etching gas used to form the plurality of concave patterns contains no oxygen substantially.

22. The manufacturing method of a semiconductor device according to claim 17, wherein the etching gas used to form the plurality of concave patterns contains no oxygen substantially.

23. The manufacturing method of a semiconductor device according to claim 16, wherein the dielectric film is SiOC film.

24. The manufacturing method of a semiconductor device according to claim 17, wherein the dielectric film is SiOC film.
